(19) United States
(12) Patent Application Publication
(10) Pub. No.: US 2014/0339290 A1
(43) Pub. Date: Nov. 20, 2014

(54) WIRE BONDING METHOD AND SEMICONDUCTOR PACKAGE MANUFACTURED USING THE SAME

(71) Applicants: Won-Gil HAN, Cheongju-si (KR); Byongjoo KIM, Asan-si (KR); Sangyoung KIM, Asan-si (KR); Tae-Gyeong CHUNG, Suwon-si (KR); Sungbok HONG, Cheonan-si (KR)

(72) Inventors: Won-Gil HAN, Cheongju-si (KR); Byongjoo KIM, Asan-si (KR); Sangyoung KIM, Asan-si (KR); Tae-Gyeong CHUNG, Suwon-si (KR); Sungbok HONG, Cheonan-si (KR)

(21) Appl. No.: 14/278,561

(22) Filed: May 15, 2014

(30) Foreign Application Priority Data
May 15, 2013 (KR) 10-2013-0055175

(51) Int. Cl. H01L 23/00

(52) U.S. Cl. CPC H01L 24/85
USPC 228/180.5

(57) ABSTRACT

Provided is a wire bonding method. The method includes: positioning a capillary having a wire inserted on a substructure including at least three connection terminals spaced apart from each other; forming an adhesive ball at a tip of the wire; bonding the adhesive ball to one of the connection terminals by lowering the capillary; and connecting the other connection terminals to the same wire by moving the capillary.

### CROSS-REFERENCE TO RELATED APPLICATIONS

This U.S. non-provisional patent application claims priority under 35 U.S.C. §119 of Korean Patent Application No. 10-2013-55175, filed on May 15, 2013, the entire contents of which are hereby incorporated by reference.

### BACKGROUND

The present disclosure herein relates to a wire bonding method, and more particularly, to a semiconductor package manufacturing process using the same.

With the development of electronics industry, demands on highly-functional, fast, and miniaturized electronic components are increased. In order to meet such demands, assembly techniques for mounting a plurality of semiconductor chips on a single package substrate have been receiving a great deal of attention lately. To connect the semiconductor chips to the package substrate, a wire bonding method and a flip chip bonding method are often used. In the wire bonding method, mounting members such as a bonding pad, a lead frame, and a printed circuit board of a semiconductor chip are connected to each other through a wire formed of metal such as gold or copper.

### SUMMARY

The present disclosure provides a wire bonding method for substantially improving the manufacturing speed and substantially reducing defects of a semiconductor package.

The present disclosure also provides a semiconductor package having improved reliability.

Embodiments of the inventive concept provide wire bonding methods including: positioning a capillary having a wire inserted therein over a substructure including at least three connection terminals spaced apart from each other; forming an adhesive ball at a tip of the wire; bonding the adhesive ball to one of the connection terminals by lowering the capillary; and continuously connecting the remaining connection terminals to the wire by moving the capillary.

In some embodiments, the continuously connecting the remaining connection terminals to the wire may include repeatedly performing: a loop operation for moving the capillary while the wire connected to the adhesive ball is inserted; and a stitch bonding operation for lowering the capillary to be adjacent to one of the remaining connection terminals, wherein the wire may be not cut off until the wire is stitch-bonded on a final connection terminal of the at least three connection terminals.

In other embodiments, the substructure may include a package substrate and at least two semiconductor chips stacked in a step form on the package substrate, wherein the connection terminals may include a substrate connection terminal included in the package substrate, a first chip connection terminal included in an uppermost semiconductor chip among the semiconductor chips, and a second chip connection terminal included in a lowermost semiconductor chip among the semiconductor chips, wherein the adhesive ball may contact the substrate connection terminal or the second chip connection terminal.

In still other embodiments, the final connection terminal o may be the second chip connection terminal or the substrate connection terminal.

In even other embodiments, each of the semiconductor chips may further include a protective layer exposing the chip connection terminal and covering a top surface of the semiconductor chip, wherein the wire may be inserted in a through hole inside the capillary; and during the stitch bonding operation, a portion of a bottom surface of the capillary may contact the protective layer and the through hole is positioned at a position overlapping the chip connection terminal.

In yet other embodiments, an angle between the bottom surface of the capillary and the top surface of the protective layer may be about 0°.

In further embodiments, the stitch-bonding of the wire to the final connection terminal may include: pressing the wire onto the connection terminal of the final position; and cutting the wire.

In still further embodiments, the forming of the adhesive ball at the tip of the wire may include causing a spark discharge at the tip of the wire.

In other embodiments of the inventive concept, semiconductor packages include: a substructure including at least three connection terminals spaced apart from each other; and a wire connected to each of the at least three connection terminals continuously, wherein the wire may include: a ball bond portion contacting one of the connection terminals; stitch bond portions contacting the remaining connection terminals; and interconnection portions connecting the ball bond portion with the stitch bond portions.

In some embodiments, top surfaces of the stitch bond portions may be substantially flat.

In other embodiments, the substructure may include a package substrate and at least two semiconductor chips stacked in a step arrangement on the package substrate, wherein the connection terminals may include a substrate connection terminal included in the package substrate, a first chip connection terminal included in an uppermost semiconductor chip among the semiconductor chips, and a second chip connection terminal included in a lowermost semiconductor chip among the semiconductor chips, wherein the adhesive ball may contact the substrate connection terminal or the second chip connection terminal.

In still other embodiments, each of the semiconductor chips may further include a protective layer exposing the chip connection terminal and covering a top surface of the semiconductor chip, wherein a top surface of the stitch bond portion may be substantially equal to or lower than a top surface of the protective layer in height.

In even other embodiments, a thickness of the stitch bond may be approximately equal to or greater than about 4 μm.

In yet other embodiments, the substrate connection terminal and the chip connection terminals may be arranged in a substantially straight line.

In further embodiments, the stitch bond portions may include a first stitch bond portion contacting two interconnection portions and a second stitch bond portion contacting one interconnection portion; and the second stitch bond portion is thinner than the first stitch bond portion.

In still further embodiments, the wire may have a crooked shape in plan view.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a view illustrating a wire bonding device according to an embodiment of the inventive concept;

FIGS. 2A and 2B are sectional views illustrating a capillary and a peripheral portion thereof according to embodiments of the inventive concept;

FIG. 3 is a sectional view illustrating a portion of a semiconductor package according to an embodiment of the inventive concept;

FIG. 4 is a process flowchart illustrating a wire bonding method according to an embodiment of the inventive concept;

FIG. 5 is a plan view illustrating a semiconductor package according to an embodiment of the inventive concept;

FIG. 6 is a sectional view taken along line A-A′ of FIG. 5;

FIGS. 7, 8A, and 9A are enlarged sectional views of portions P1, P2, and P3 of FIG. 6, respectively;

FIGS. 8B and 9B are perspective views of FIGS. 8A and 9A, respectively;

FIG. 10 is a sectional view taken along a line B-B′ of FIG. 6.

FIGS. 11, 12A, 13, 14A, 15, 16, 17, 18A, 19A, and 20 are sectional views sequentially illustrating a process for manufacturing a semiconductor package having the section of FIG. 6;

FIGS. 12B, 14B, 18B, and 19B are enlarged views of P4, P5, P6, and P7 of FIGS. 12A, 14A, 18A, and 19A, respectively.

FIG. 21 is a picture of a semiconductor package according to some embodiments of the inventive concept;

FIG. 22 is a view illustrating a package module including a semiconductor package according to an embodiment of the inventive concept;

FIG. 23 is a block diagram illustrating an electronic device including a semiconductor package according to some embodiments of the inventive concept; and

FIG. 24 is a block diagram illustrating a memory system including a semiconductor package according to another embodiment of the inventive concept.

### DETAILED DESCRIPTION OF THE EMBODIMENTS

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

Hereinafter, exemplary embodiments of the inventive concept will be described in detail with reference to the accompanying drawings.

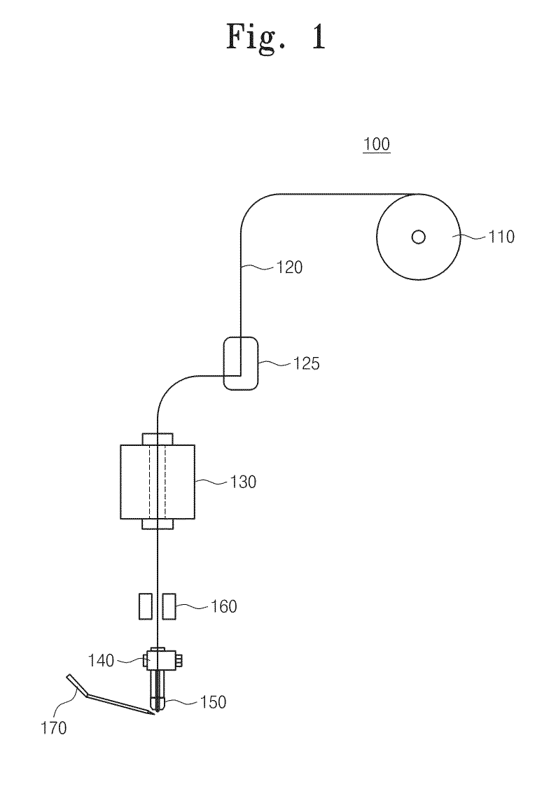

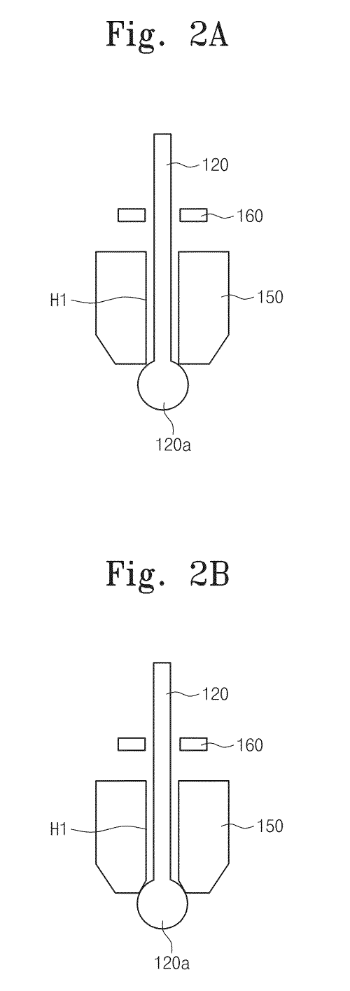

FIG. 1 is a view illustrating a wire bonding device according to an embodiment of the inventive concept. FIGS. 2A and 2B are cross-sectional views illustrating a capillary and a peripheral portion of the wire bonding device according to some embodiments of the inventive concept.

Referring to FIGS. 1, 2A, and 2B, the wire bonding device 100 may include a spool unit 110, a wire guide 125, an air clamp 130, a capillary 150, a cut clamp 160, and a discharge rod 170. The spool unit 110 may include a spool having a wound wire. The wire may be a conductive wire such as a copper wire or a gold wire having an excellent electrical conductivity. The wire 120 may pass through the wire guide 125 and the air camp 130 to be inserted into a through hole H1 of the capillary 150. The air clamp 130 serves to pull the wire 120 in a direction toward the spool 110 (i.e., a rearward direction). The capillary 150 may be supported by a transducer 140, and the capillary 150 is designed to move in each of the xyz directions to connect the wire 120 to a plurality of bonding pads and to an electrode of a mounting member.

Moreover, the transducer 140 may be installed at both sidewalls of the capillary 150 to support it, and to press the tip of the capillary 150 toward a connection target (i.e., a bonding pad or an electrode of a mounting member), and to provide ultrasonic vibration to the capillary 150.

The cut clamp 160 may be disposed between the capillary 150 and the air clamp 130. Further, the discharge rod 170 may be disposed around the tip of the capillary 150. The cut clamp 160 may be installed at both sides of the wire 120 to grab and loosen the wire 120 and also to provide a predetermined potential to the wire 120. Moreover, the cut clamp 160 serves to apply tension to the wire 120 positioned in the capillary 150 to cut the wire 120. Furthermore, the discharge rod 170 also receives a predetermined potential, i.e., a discharge voltage, and serves to form an adhesive ball 120a at the tip of the wire 120, while contacting the tip of the wire 120 passing through the capillary 150. At this point, the discharge rod 170 moves along the movement of the capillary 150.

Here, the adhesive ball 120a may be formed at the tip of the wire 120 by instantaneous spark discharge when the wire 120, receiving a predetermined potential from the cut clamp 160, contacts the discharge rode 170. That is, the adhesive ball 120a is formed when the tip of the wire 120 is instantaneously melted by the spark discharge. The adhesive ball 120a may then cool down.

Referring to FIGS. 2A and 2B, when the wire bonding device 100 is about to perform a bonding operation on a predetermined portion, since the wire 120 may be provided on the predetermined portion, the cut clamp 160 may not be tightened but may be open. However, at this moment, the wire 120 may be pulled to the rear by the air clamp 130. Even when no adhesive ball 120a or the adhesive ball 120a is formed at the tip of the wire 120, if the adhesive ball 120a has a smaller diameter than the through hole H1, the wire 120 may fall back into the capillary 150. In this case, defective processes may occur. Therefore, in order to prevent defective processes, the adhesive ball 120a should be formed to have a larger diameter than the through hole H1. In this way, the wire 120 can be substantially prevented from falling back into the capillary 150 with the adhesive ball 120a having a larger diameter than the through hole H1 being caught by the bottom of the capillary 150. The bottom surface of the capillary 150 may have an angle of about 0° with respect to a horizontal plane. The inner diameter of the through hole H1 may be approximately constant depending on the height as shown I FIG. 2A, or may become wider at the bottom as shown in FIG. 2B.

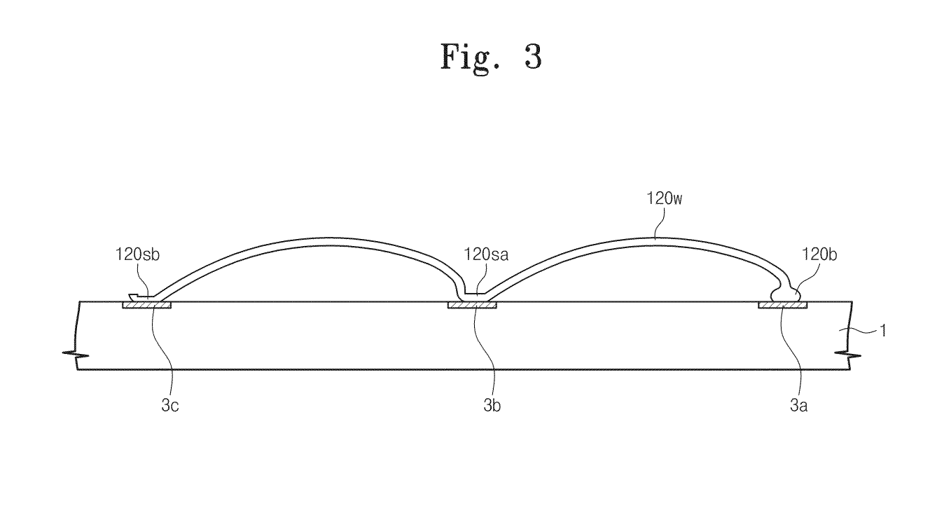

FIG. 3 is a sectional view illustrating a portion of a semiconductor package according to an embodiment of the inventive concept.

Referring to FIG. 3, the semiconductor package may include a substructure 1 including at least three connection terminals 3a, 3b, and 3c spaced apart from each other. The substructure 1 may include at least one of a package substrate and a semiconductor chip. The connection terminals 3a, 3b, and 3c are connected to wire interconnection structures 120b, 120w, 120sa, and 120sb. The wire interconnection structures 120b, 120w, 120sa, and 120sb includes a bond portion 120b contacting a first connection terminal 3a, a first stitch bond portion 120sa contacting the second connection terminal 3b, a second stitch bond portion 120sb contacting the third connection terminal 3c, and interconnection portions 120w connecting them. The top surface of a ball bond portion 120b may be protruding. The stitch bond portions 120sa and 120sb are substantially flat. The first stitch bond portion 120sa is connected to the two adjacent interconnection portions 120w, and the second stitch bond portion 120sb is connected to one interconnection portion 120w. A thickness of the first stitch bond portion 120sa may be equal to or thicker than that of the second stitch bond portion 120sb.

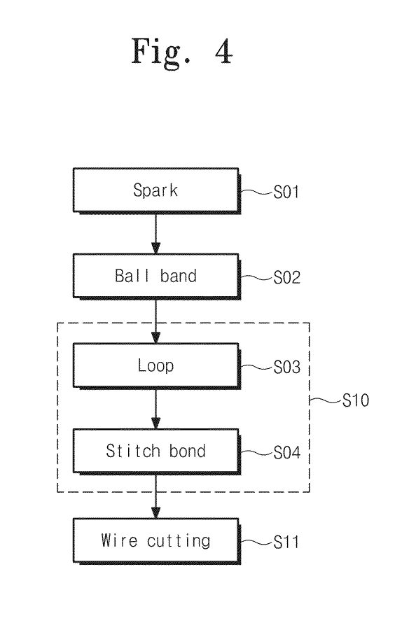

FIG. 4 is a process flowchart illustrating a wire bonding method according to an embodiment of the inventive concept.

Referring to FIGS. 1, 3, and 4, according to a process for manufacturing the semiconductor package of FIG. 3, the discharge rod 170 causes a spark to form the adhesive ball 120a at the tip of the wire 120 in operation 501. Then, by lowering the capillary 150 to press the adhesive ball 120a to the first connection terminal 3a and providing ultrasonic vibration (and optional heat treatment to the first connection terminal 3a or surrounding areas), a ball bond process for forming the interconnection portion 120w is performed in operation S2. While the ball bond portion 120b is attached to the first connection terminal 3a, the capillary 150 moves toward the second connection terminal 3b to perform a loop process for forming the interconnection portion 120w in operation S03. By pressing the second wire 120 with the capillary 150 on the second connection terminal 3b and then performing an ultrasonic welding operation, the wire 120 is stitch-bonded in operation S04 to form the first stitch bond portion 120sa. Then, by moving the capillary 150 to the second connection terminal 3c again, a loop process for forming the interconnection portion 120w is performed in operation S03, and then by stitch-bonding the wire 120 on the third connection terminal 3c in operation S04, the second stitch bond portion 120sb is formed. At least from the ball bond operation (i.e., operation S02) to the stitch bond operation (i.e., operation S04), the cut clamp 160 may not tighten the wire 120 and may be open. Once a wire interconnection structure is formed at a final connection terminal 3c, i.e., at a desired final position, the cut clamp 160 tightens the wire 120 and raises the capillary 150 to cut the wire 120 in operation S11.

According to this embodiment, since there are three connection terminals that a wire interconnection structure interconnects, a loop-stitch bond operation (i.e., operation S10) including the loop operation (i.e., operation S03) and the stitch bond operation (i.e., operation S04) may be performed twice. However, when the number of connection terminals that the wire interconnection structure connects is greater than three, the number of times in which the loop-stitch bond operation (i.e., operation S10) is repeated may be greater than two.

In a wire bonding method according to an embodiment of the inventive concept, when a wire connecting at least three connection terminals is continuously formed, an adhesive ball may be formed once for ball bonding to one of the at least three connection terminals and the remaining portion of the wire may be stitch-bonded to the other connection terminals. Therefore, compared to a process for forming an adhesive ball each time, a cutting operation and a spark operation for forming an adhesive ball may be reduced, so that processing speed may be improved. Furthermore, since the number of forming an adhesive ball is reduced, the secondary defect frequency occurring when a defective adhesive ball is formed may be reduced. As a result, a semiconductor package having improved reliability may be provided.

Then, a semiconductor package according to an embodiment of the inventive concept will be described in more detail.

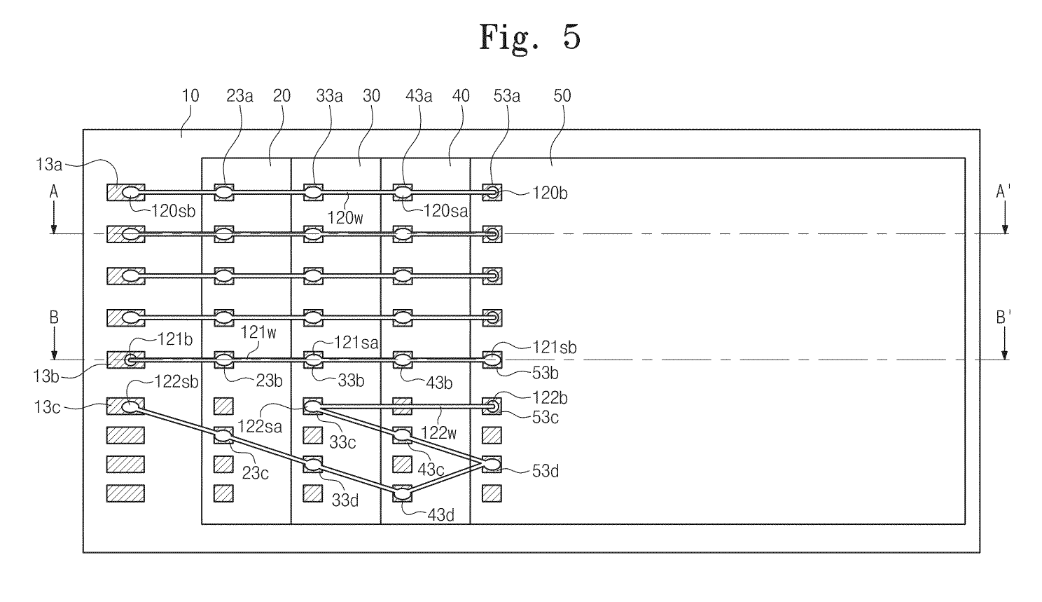

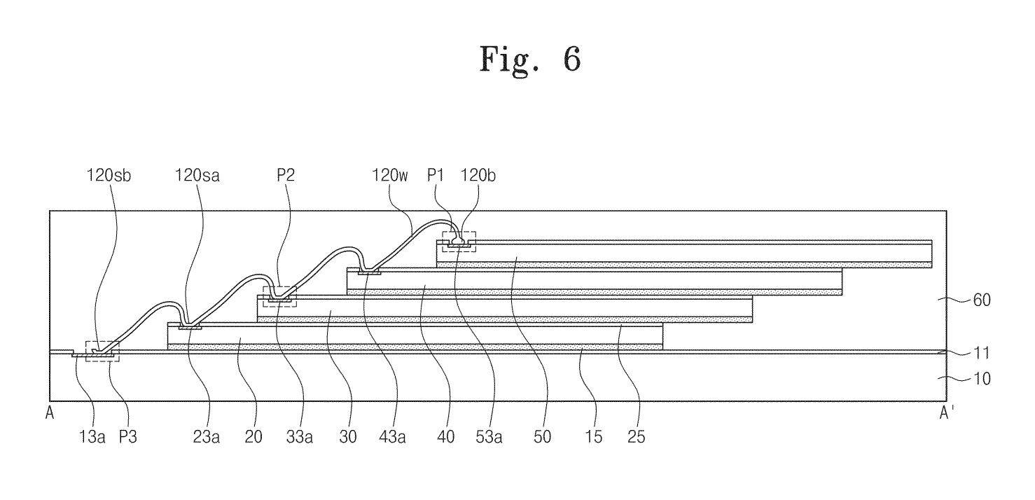

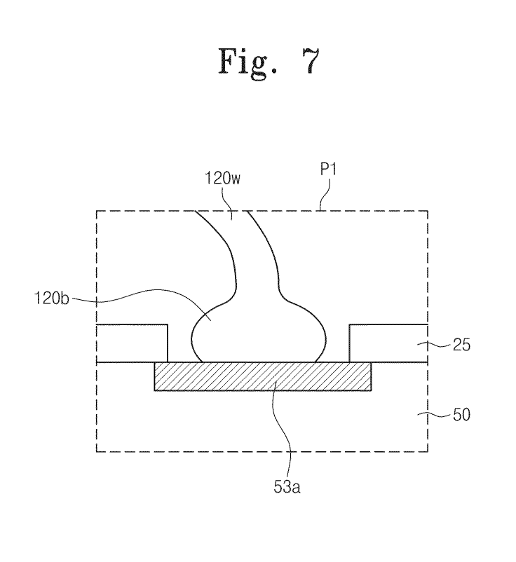

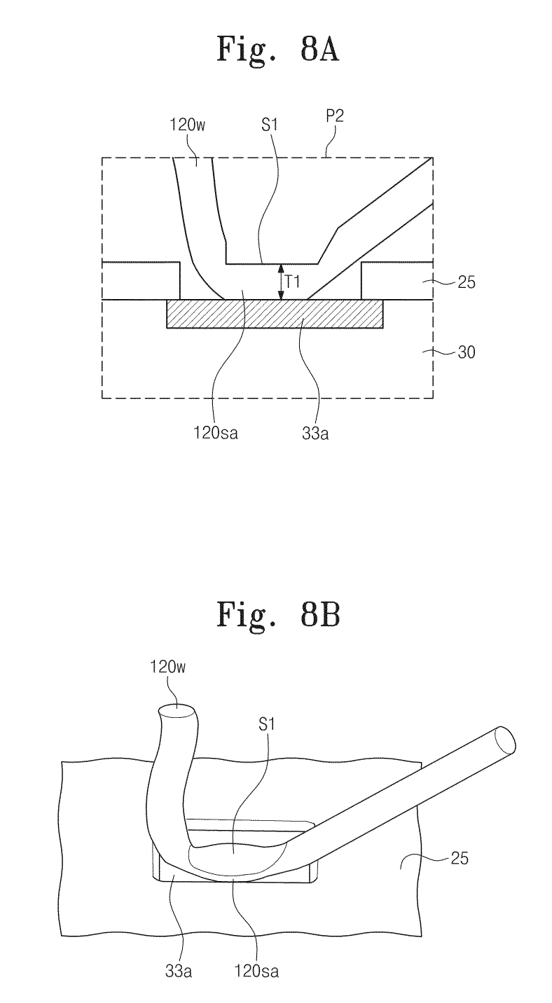

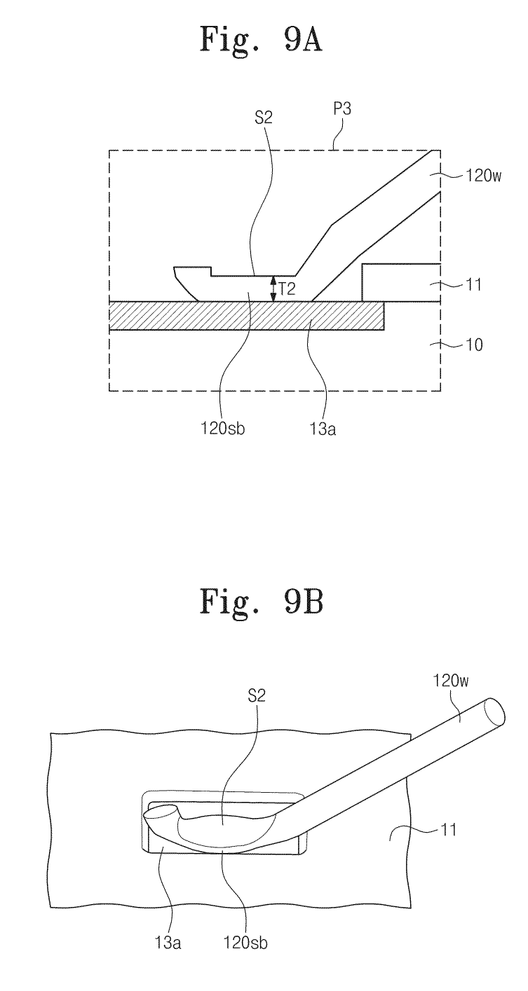

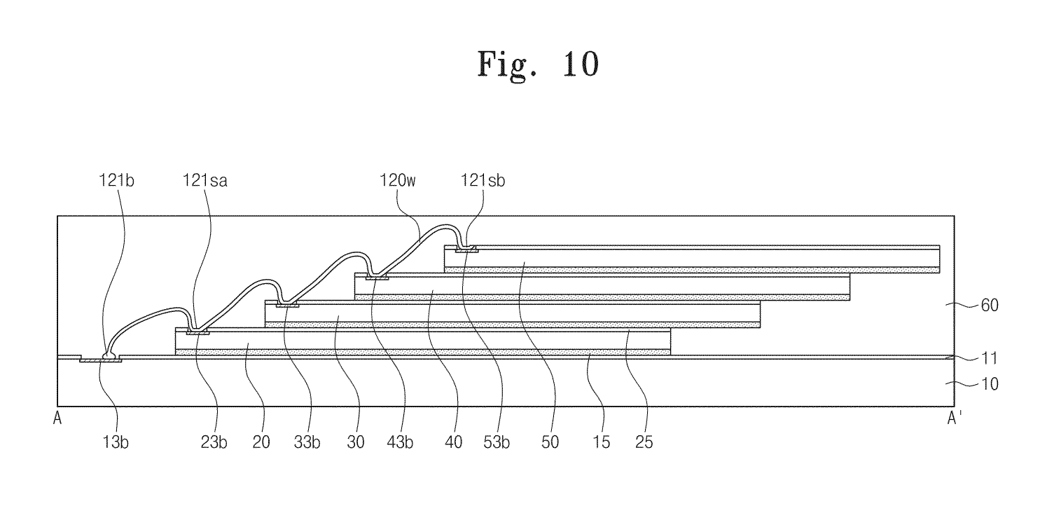

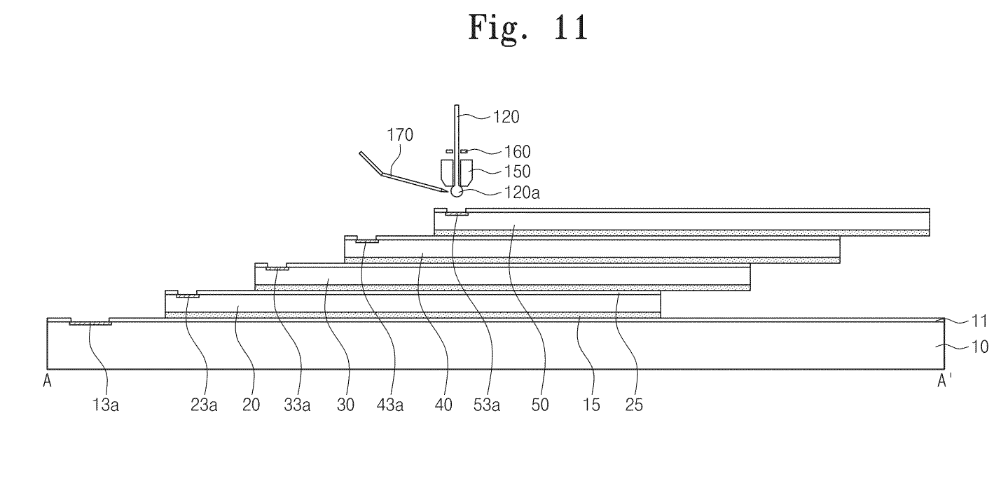

FIG. 5 is a plan view illustrating a semiconductor package according to some embodiments of the inventive concept. FIG. 6 is a sectional view taken along line A-A′ of FIG. 5. FIGS. 7, 8A, and 9A are enlarged sectional views of portions P1, P2, and P3 of FIG. 6, respectively. FIGS. 8B and 9B are perspective views of FIGS. 8A and 9A, respectively. FIG. 10 is a sectional view taken along line B-B′ of FIG. 6.

First, referring to FIGS. 5, 6, 7, 8A, 8B, 9A, and 9B, first to fourth semiconductor chips 20, 30, 40, and 50 are sequentially stacked in a step form or step arrangement on the package substrate 10. First to third substrate connection terminals 13a, 13b, and 13c are spaced apart from each other on one end of the package substrate 10. The top surface of the package substrate 10 may be covered with a substrate protective layer 11. Eleventh to thirteenth connection terminals 23a, 23b, and 23c spaced apart from each other may be disposed on the exposed one end of the first semiconductor chip 20. Twenty first to twenty fourth connection terminals 33a, 33b, 33c, and 33d spaced apart from each other may be disposed on the exposed one end of the second semiconductor chip 30. Thirty first to thirty fourth connection terminals 43a, 43b, 43c, and 43d are disposed on the exposed one end of the third semiconductor chip 40. Forty first and forty fourth connection terminals 53a, 53b, and 53c spaced apart from each other may be disposed on the exposed one end of the fourth semiconductor chip 50. Each of the semiconductor chips 20, 30, 40, and 50 may be covered with a chip protective layer (or a passivation layer) 25. Each of the semiconductor chips may be attached to the package substrate 10 by an adhesive layer 15. The semiconductor chips 20, 30, 40, and 50 may be covered with a mold layer 60. However, depending on the applications, other suitable encapsulants such as a ceramic casing may be used.

In plan view, the first substrate connection terminal 13a, the eleventh chip connection terminal 23a, the twenty first chip connection terminal 33a, the thirty first chip connection terminal 43a, and the forty first chip connection terminal 53a may be arranged on a substantially straight line, and are electrically connected to each other by first wire interconnection structures 120b, 120w, 120sa, and 120sb. The first wire interconnection structures 120b, 120w, 120sa, and 120sb include a first ball bond portion 120b contacting the forty first chip connection terminal 53a, the eleventh stitch bond portion 120sa contacting the eleventh to thirty first chip connection terminals 23a, 33a, and 43a, the twenty first stitch bond portion 120sb contacting the first substrate connection terminal 13a, and the first interconnection portions 120w connecting them. The top surface of the first ball bond portion 120b may be protruding. The top surfaces S1 and S2 of the eleventh and twenty first stitch bond portions 120sa and 120sb may be substantially flat. The top surfaces S1 and S2 of the eleventh and twenty first stitch bond portions 120sa and 120sb may be substantially equal to or higher than the top surface of the chip protective layer 25. The eleventh stitch bond portion 120sa may be connected to the two first interconnection portions 120w and the twenty first stitch bond portion 120sb may be connected to one first interconnection portion 120w. The first thickness T1 of the eleventh stitch bond portion 120sa may be substantially equal to or thicker than the second thickness T2 of the twenty first stitch bond portion 120sb. The first thickness T1 may be equal to or greater than about 4 μm.

Referring to FIGS. 5 and 10, in plan view, the second substrate connection terminal 13b, the twelfth chip connection terminal 23b, the twenty second chip connection terminal 33b, the thirty second chip connection terminal 43b, and the forty second chip connection terminal 53b may be arranged along a substantially straight line, and may be electrically connected to each other by the second wire interconnection structure 121b, 121w, 121sa, and 121sb. The second wire interconnection structures 121b, 121w, 121sa, and 121sb include a first ball bond portion 121b contacting the second substrate connection terminal 13b, the twelfth stitch bond portion 121sa contacting the twelfth to thirty second chip connection terminals 23b, 33b, and 43b, the twenty second stitch bond portion 121sb contacting the forty second chip connection terminal 53a, and the second interconnection portions 121w connecting them. The top surface of the second ball bond portion 121b may be protruding. The top surfaces S1 and S2 of the twelfth and twenty second stitch bond portions 121sa and 121sb may be substantially flat. The twelfth stitch bond portion 121sa may be connected to the two second interconnection portions 121w and the twenty second stitch bond portion 121sb may be connected to one second interconnection unit 121w.

In some embodiments, the interconnection portions and the stitch bond portions form a generally downwardly cascading wave shape or downwardly progressing wave shape.

Referring to FIG. 5 again, the third wire interconnection structures 122b, 122w, 122sa, and 122sb include the third ball bond portion 122b contacting the forty third chip connection terminal 53c, the thirteenth stitch bond portions 122sa contacting the twenty third chip connection terminal 33c, the thirty third chip connection terminal 43c, the forty fourth chip connection terminal 53d, the thirty fourth chip connection terminal 43d, the twenty fourth chip connection terminal 33d, and the thirteenth chip connection terminal 23c, the twenty third stitch bond portion 122sb contacting the third substrate connection terminal 13c, and third interconnection portions 122w connecting them. The third wire interconnection structures 122b, 122w, 122sa, and 122sb may have a crooked shape in plan view.

A method of manufacturing the semiconductor package will be described in more detail.

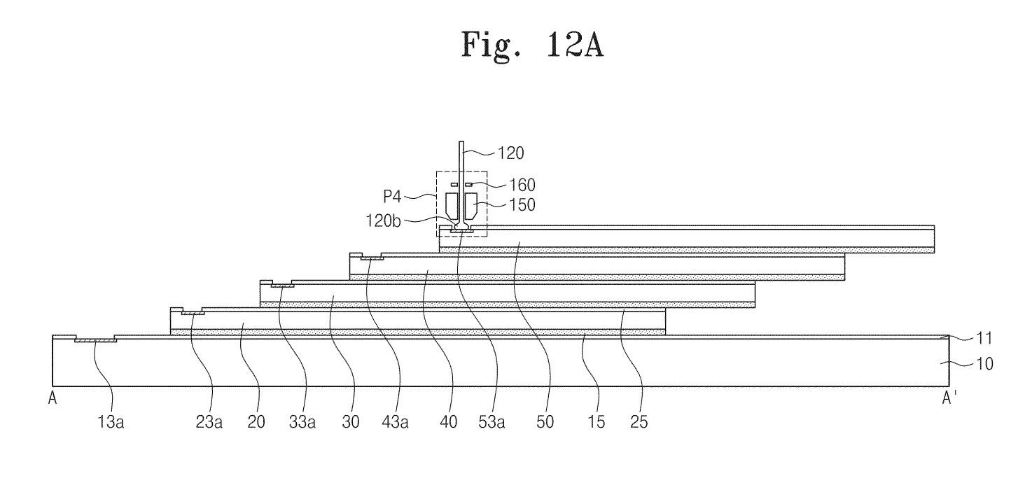

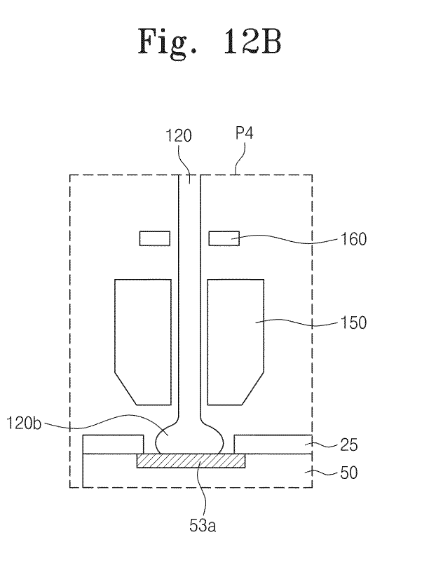

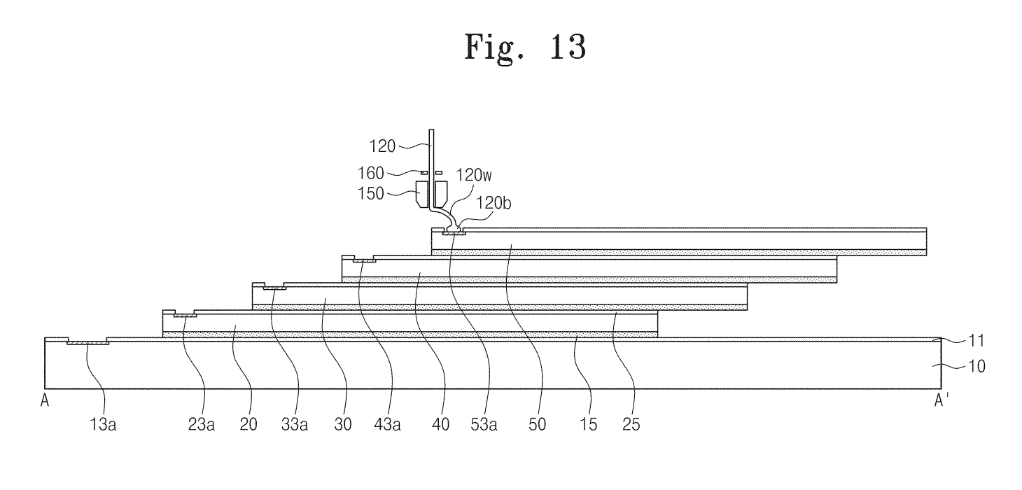

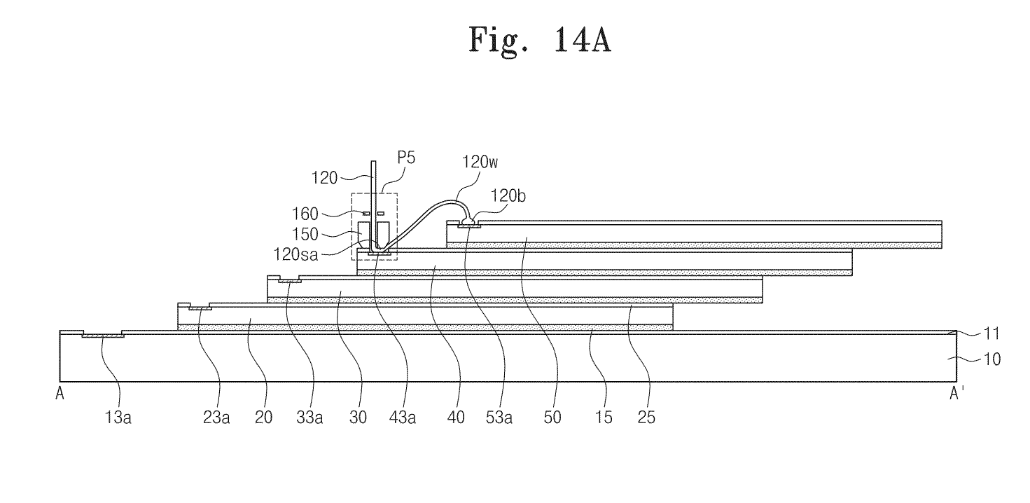

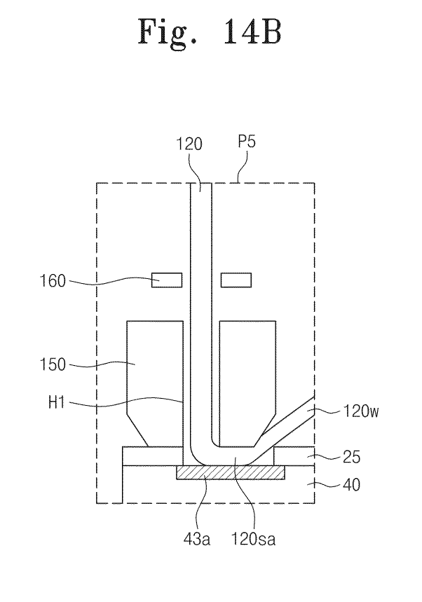

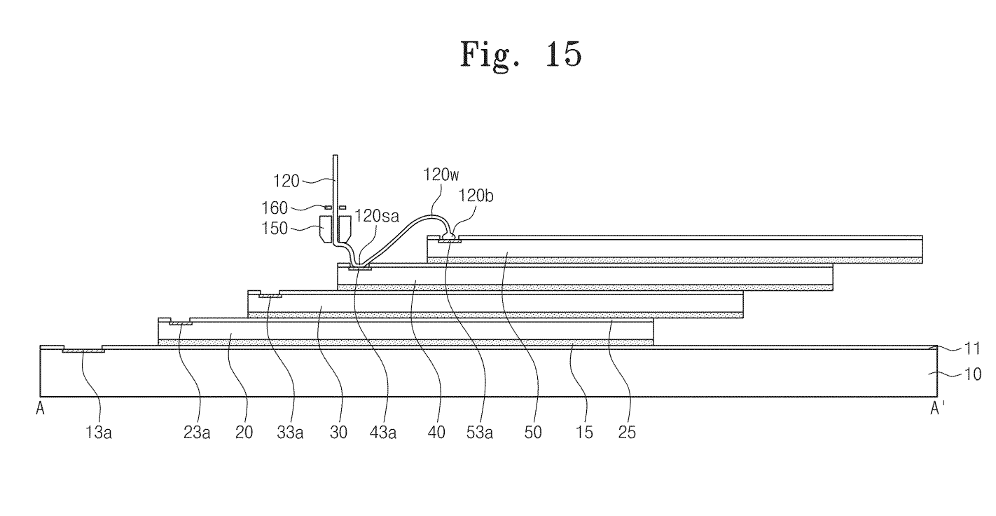

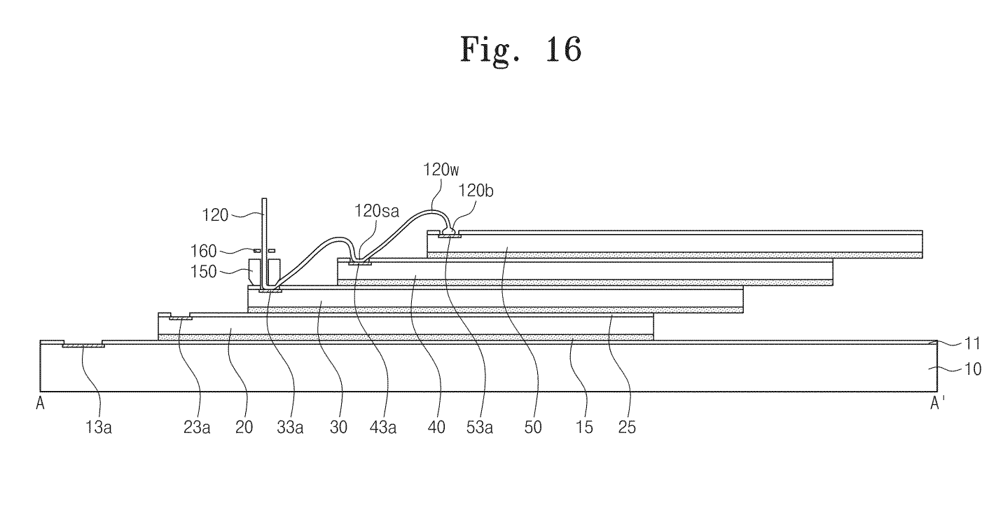

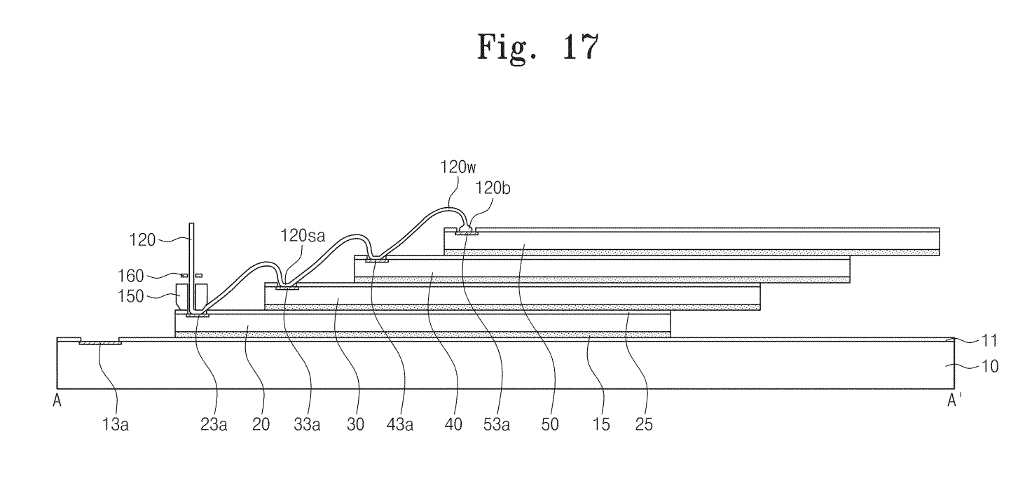

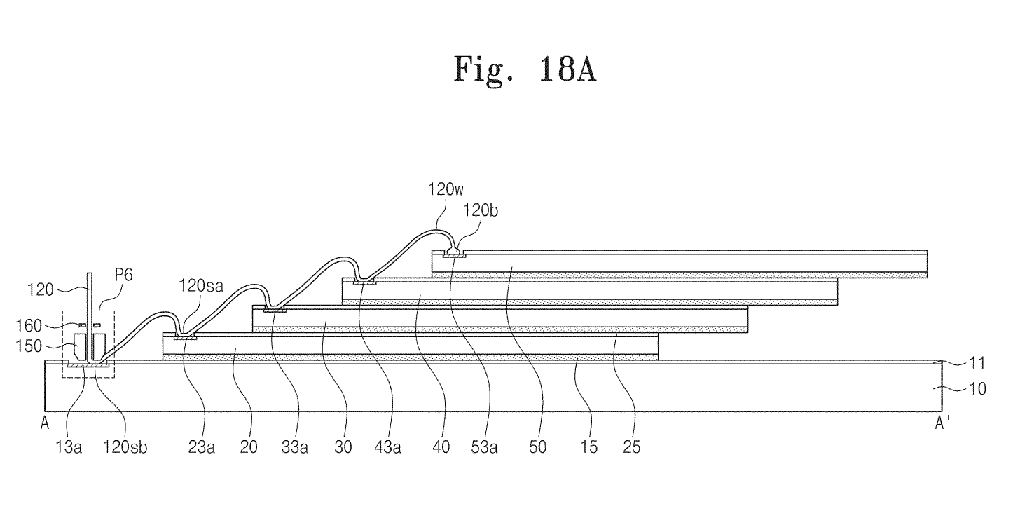

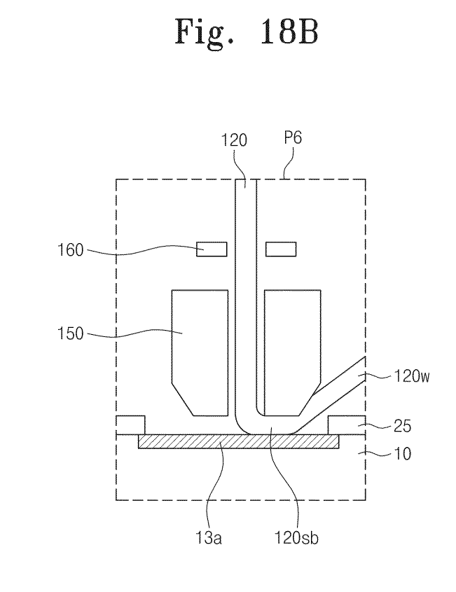

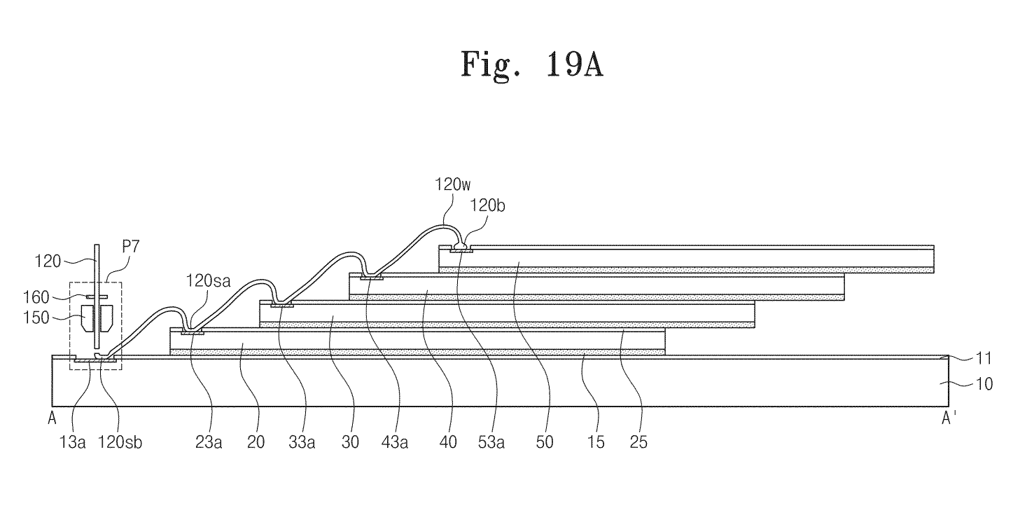

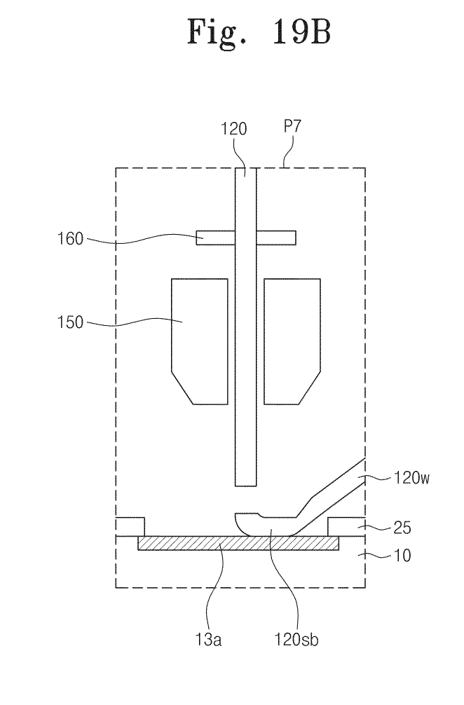

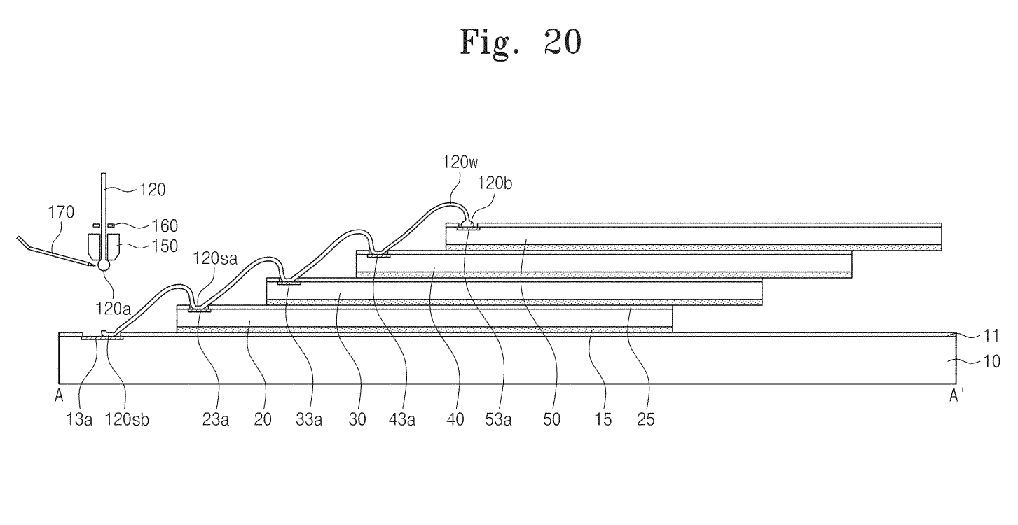

FIGS. 11, 12A, 13, 14A, 15, 16, 17, 18A, 19A, and 20 are sectional views sequentially illustrating a process for manufacturing a semiconductor package having the section of FIG. 6. FIGS. 12B, 14B, 18B, and 19B are enlarged views of P4, P5, P6, and P7 of FIGS. 12A, 14A, 18A, and 19A, respectively.

Referring to FIGS. 1, 4, and 11, the ends of the first to fourth semiconductor chips 20, 30, 40, and 50 are stacked to have a step form on the package substrate 10 and the adhesive layer 15 may be used to bond them. The discharge rod 170 causes a spark to form the adhesive ball 120a at the tip of the wire 120. At this point, the cut clamp 160 may be open.

Referring to FIGS. 1, 4, 12A, and 12B, by lowering the capillary 150 to press the adhesive ball 120a to the forty first chip connection terminal 53a and providing ultrasonic vibration (optionally with heating the terminal 53a), a ball bond process for forming the first ball band portion 120b is performed in operation S02. At this point, the cut clamp 160 may still be open.

Referring to FIGS. 1, 4, and 13, while the first ball bond portion 120b is attached, the capillary 150 moves in a direction toward the thirty first chip connection terminal 43a to perform a loop process for forming the first interconnection portion 120w. At this point, the cut clamp 160 may still be open.

Referring to FIGS. 1, 4, 14A, and 14B, the wire 120 may be stitch-bonded to the thirty first chip connection terminal 43a so as to form the eleventh stitch bond portion 120sa. At this point, the bottom surface of the capillary 150 may contact the top surface of the chip protective layer 25. Then, the capillary 150 may be placed to allow the through hole H1 to overlap the thirty first chip connection terminal 43a. Thereby, the wire is pressed toward one bottom surface of the capillary 150, but the other bottom surface of the capillary 150 may contact and be supported by the chip protective layer 25, so that the wire 120 is not pressed excessively. A thickness of the eleventh stitch bond portion 120sa formed according thereto may be substantially equal to or less than that of the chip protective layer 25. Additionally, since the wire 120 is not pressed excessively, it may not be cut off even when a loop process is performed again. The bottom surface of the capillary 150 may be substantially flat and thus make an angle with the top surface of the chip protective layer 25 of about 0°. Therefore, compared to the pointed bottom surface of the capillary 150, the power that the capillary 150 presses is distributed, so that the damage to the chip protective layer 25 or the thirty first connection terminal 43a may be substantially prevented. At this point, the cut clamp 160 may still be open.

Referring to FIGS. 1, 4, and 15, while the eleventh stitch bond portion 120sa is attached on the thirty first chip connection terminal 43a, the capillary 150 moves in a direction toward the twenty first chip connection terminal 33a to perform a loop process for forming the first interconnection portion 120w. At this point, the cut clamp 160 may still be open.

Referring to FIGS. 1, 4, and 16, the wire 120 is stitch-bonded on the twenty first chip connection terminal 33a so as form the eleventh stitch bond portion 120sa in operation S04. At this point, the cut clamp 160 may still be open.

Referring to FIGS. 1, 4, and 17, while the eleventh stitch bond portion 120sa is attached on the twenty first chip connection terminal 33a, the capillary 150 moves in a direction toward the eleventh chip connection terminal 23a to perform a loop process for forming the first interconnection portion 120w in operation S03. Then, the wire 120 is stitch-bonded on the eleventh chip connection terminal 23a to form the eleventh stitch bond portion 120sa in operation S04.

Referring to FIGS. 1, 4, 18A, and 18B, while the eleventh stitch bond portion 120sa is attached on the eleventh chip connection terminal 23a, the capillary 150 moves toward the first substrate connection terminal 13a to perform a loop process for forming the first interconnection portion 120w in operation S03. Then, the wire 120 may be stitch-bonded to the first substrate connection terminal 13a to form the twenty first stitch bond portion 120sb. At this point, since a width of the first substrate connection terminal 13a exposed by the substrate protective layer 11 is broader than the bottom width of the capillary 150, the bottom surface of the capillary 150 may not contact the substrate protective layer 11. Accordingly, when the capillary 150 is pressed on the eleventh chip connection terminal 23a, it may not be supported by the substrate protective layer 11. As a result, the wire 120 may be further pressed compared to when the wire 120 forms the eleventh stitch bond portion 120sa. Therefore, the twenty first stitch bond portion 120sb may have a thinner thickness than the eleventh stitch pond portion 120sa. Thereby, the first wire interconnection structures 120b, 120sa, 120sb, and 120w may be formed.

Referring to FIGS. 1, 4, 19A, and 19B, after forming the first wire interconnection structures 120b, 120sa, 120sb, and 120w, the cut clamp 160 is tightened to grab the wire 120. Then, when the capillary 150 is raised, a pressed dent portion is formed in the wire 120, and the mechanical strength thereof is deteriorated, so that the wire 120 may be cut. Therefore, the wire 120 is cut in operation S11. At this point, one end of the twenty first stitch bond portion 120sb may or may not protrude.

Referring to FIGS. 1, 4, 5, and 20, the discharge rod 170 causes spark at the tip of the wire 120 so as to form the adhesive ball 120a. Then, by repeating the above process, the second wire interconnection structures 121b, 121sa, 121sb, and 121w and the third wire interconnection structures 122b, 122sa, 122sb, and 122w may be sequentially formed. When the second wire interconnection structures 121b, 121sa, 121sb, and 121w are formed, a direction of progression of the capillary 150 may be opposite to when the first wire interconnection structures 120b, 120sa, 120sb, and 120w are formed. When the third wire interconnection structures 122b, 122sa, 122sb, and 122w are formed, the capillary 150 may move in a crooked or zigzag manner. Then, the mold layer 60 is formed.

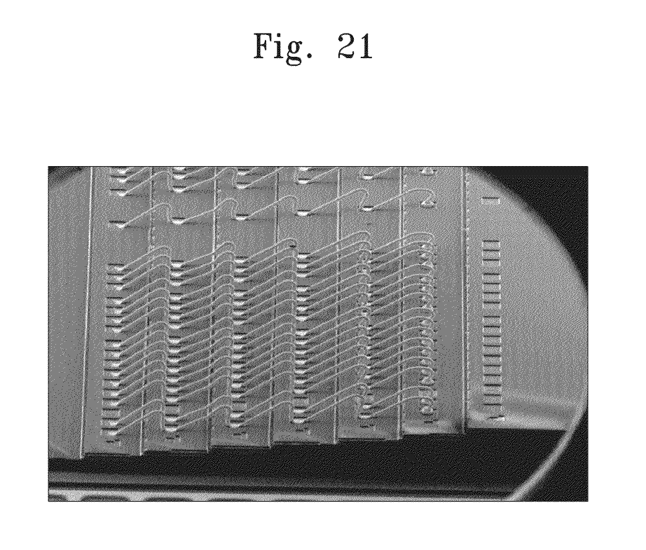

FIG. 21 is an image illustrating a semiconductor package formed according to an embodiment of the inventive concept.

Referring to FIG. 21, as mentioned above, wire interconnection structures including one ball bond portion and a plurality of stitch bonding portions may be formed well.

The above semiconductor package technique may be applied to various kinds of semiconductor devices and a package module including the same.

Also, in some embodiments, although not illustrated, a through silicon via (TSV) may be formed in one or more semiconductor chips to be coupled to chip connection terminals discussed above to be electrically coupled to the wire interconnection structures discussed above.

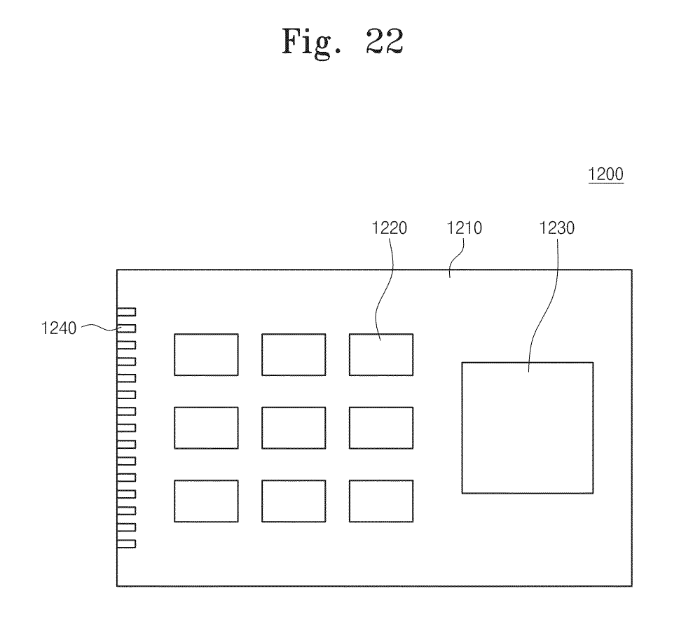

FIG. 22 is a view illustrating a package module including a semiconductor package according to an embodiment of the inventive concept. Referring to FIG. 22, the package module 1200 may be provided as a semiconductor integrated circuit chip 1220 and a Quad Flat Package (QFP) semiconductor integrated circuit chip 1230. The semiconductor devices 1220 and 1230 of a semiconductor package technique according to an embodiment of the inventive concept are installed on the substrate 1210, so that the package module 1200 may be formed. The package module 1200 may be connected to an external electronic device through an external connection terminal 1240 at one side of the substrate 1210.

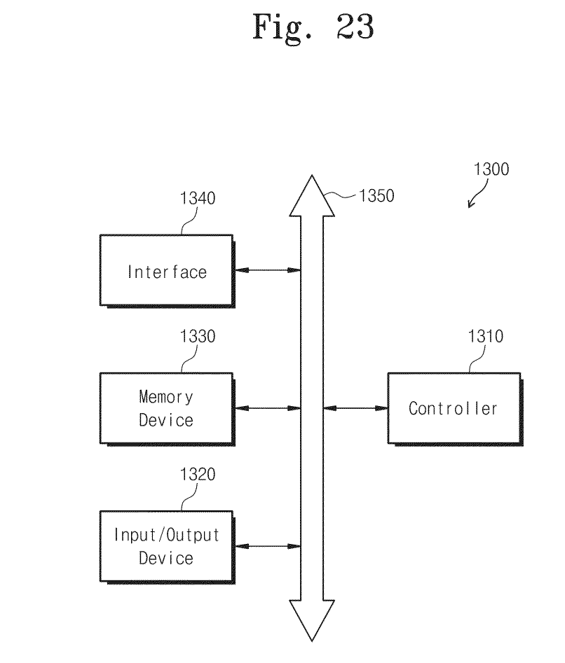

The semiconductor package technique may be applied to an electronic system. FIG. 23 is a block diagram illustrating an electronic device including a semiconductor package according to an embodiment of the inventive concept. Referring to FIG. 23, the electronic system 1300 may include a controller 1310, an input/output device 1320, and a memory device 1330. The controller 1310, the input/output device 1320, and the memory device 1330 may be connected to each other through a bus 1350. The bus 1350 is a path through which data move. For example, the controller 1310 may include at least one of a microprocessor, a digital signal processor, a microcontroller, and logical devices performing the same function as them. The controller 1310 and the memory device 1330 may include a semiconductor package according to an embodiment of the inventive concept. The input/output device 1320 may include at least one of a keypad, a keyboard, and a display device. The memory device 330 stores data. The memory device 1330 may store data and/or commands executed by the controller 1310. The memory device 1330 may include a volatile memory device and/or a nonvolatile memory device. Or, the memory device 1330 may include flash memory. For example, a flash memory according to an embodiment of the inventive concept may be mounted on a mobile device or a desktop computer. Such a flash memory may include a semiconductor disk device (SSD). In this case, the electronic system 1300 may stably store a large amount of data in the flash memory system. The electronic system 1300 may further include an interface 1340 to transmit data to a communication network or receive data from a communication network. The interface 1340 may be in a wired/wireless form. For example, the interface 1340 may include an antenna or a wired/wireless transceiver. Also, although not shown in the drawings, it is apparent to those skilled in the art that the electronic system 1300 may further include an application chipset, a camera image processor (CIS), and an input/output device.

The electronic device 1300 may be realized with a mobile system, a personal computer, an industrial computer, or a logic system performing various functions. For example, the mobile system may be one of a personal digital assistant (PDA), a portable computer, a web tablet, a mobile phone, a wireless phone, a laptop computer, a memory card, a digital music system, and an information transmitting/receiving system. When the electronic system 1300 is equipment for performing wireless communication, it may use a communication interface protocol of a third generation communication system such as CDMA, GSM, NADC, E-TDMA, WCDAM, and CDMA2000.

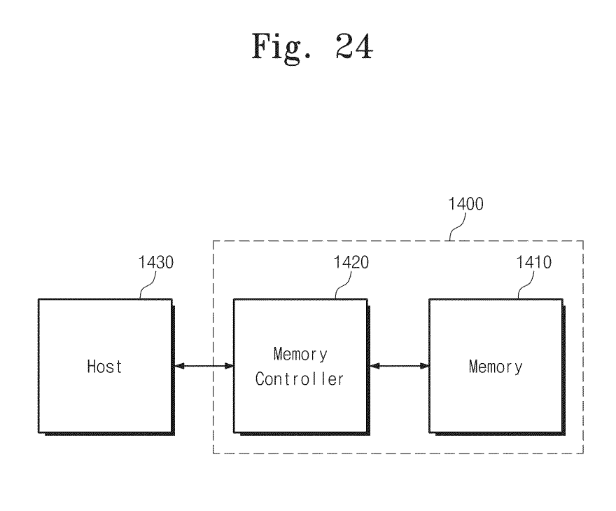

The semiconductor device according to an embodiment of the inventive concept may be provided in a memory card form. FIG. 24 is a block diagram illustrating a memory system including a semiconductor package according to an embodiment of the inventive concept. Referring to FIG. 24, the memory card 1400 may include a nonvolatile memory device 1410 and a memory controller 1420. The nonvolatile memory device 1410 and the memory controller 1420 may store data or read stored data. The nonvolatile memory device 1410 may include at least one of nonvolatile memory devices according to an embodiment of the inventive concept. The memory controller 1420 may read data stored data or may control the flash memory device 1410 to store data in response to a read/write request.

According to an embodiment of the inventive concept, in relation to a wire bonding method, when a wire that continuously connected at least three connection terminals is formed, a bonding ball is formed once and the remaining is formed through stitch bonding. Therefore, compared to a process for forming the bonding ball each time, a cutting process and a spark process for forming the bonding ball may be reduced. As a result, processing speed may be improved. Moreover, the number of forming the bonding ball is reduced, so that secondary defect frequency occurring when a defective bonding ball is formed may be reduced. As a result, a semiconductor package having improved reliability may be provided.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

1. A wire bonding method comprising:
positioning a capillary having a wire inserted therein over a substructure including at least three connection terminals spaced apart from each other;
forming an adhesive ball at a tip of the wire;
bonding the adhesive ball to one of the at least three connection terminals by lowering the capillary; and
connecting the other connection terminals to the wire by moving the capillary.

2. The method of claim 1, wherein connecting the wire to the other connection terminals comprises repeatedly performing:
a loop operation for moving the capillary while the wire connected to the adhesive ball is inserted therein; and
a stitch bonding operation for lowering the capillary to be adjacent to one of the other connection terminals,
wherein the wire is not cut off until the wire is stitch-bonded on a final connection terminal of the at least three connection terminals.

3. The method of claim 2, wherein the substructure comprises a package substrate and at least two semiconductor chips stacked in a step form on the package substrate,
wherein the at least three connection terminals comprise a substrate connection terminal included in the package substrate, a first chip connection terminal included in an uppermost semiconductor chip among the semiconductor chips, and a second chip connection terminal included in a lowermost semiconductor chip among the semiconductor chips,
wherein the adhesive ball contacts the substrate connection terminal or the second chip connection terminal.

4. The method of claim 3, wherein the final connection terminal comprises the second chip connection terminal or the substrate connection terminal.

5. The method of claim 3, wherein each of the semiconductor chips further comprises a protective layer exposing the chip connection terminal and covering a top surface of the semiconductor chip,
wherein the wire is inserted in a through hole inside the capillary; and
during the stitch bonding operation, a portion of a bottom surface of the capillary contacts the protective layer and the through hole is positioned at a position overlapping the chip connection terminal.

6. The method of claim 5, wherein an angle between the bottom surface of the capillary and the top surface of the protective layer is about 0°.

7. The method of claim 2, wherein the stitch-bonding of the wire to the final connection terminal comprises:
pressing the wire onto the final connection terminal; and
cutting the wire.

8. The method of claim 1, wherein the forming of the adhesive ball at the tip of the wire comprises causing a spark discharge at the tip of the wire.

9-16. (canceled)

17. A wire bonding method comprising:
providing a substructure including at least three connection terminals;
bonding an adhesive ball at a tip of a wire to one of the at least three connection terminals to form a ball bond portion thereon; and
connecting the other connection terminals to the same wire.

18. The method of claim 17, wherein connecting the other connection terminals to the same wire includes forming stitch bond portions using the wire to contact the other connection terminals and interconnection portions connecting the ball bond portion with the stitch bond portions.

19. The method of claim 17, wherein bonding an adhesive ball comprises positioning a capillary having the wire inserted therein over one of the at least three connection terminals.

20. (canceled)

21. (canceled)
